(19) United States
(12) Patent Application Publication
(10) Pub. No.: US 2022/0270812 A1
(43) Pub. Date: Aug. 25, 2022

(54) INDUCTOR AND INTEGRATED CIRCUIT

(71) Applicant: Realtek Semiconductor Corporation, Hsinchu (TW)

(72) Inventors: Chieh-Pin CHANG, Hsinchu (TW); Cheng-Wei LUO, Hsinchu (TW); Kai-Yi HUANG, Hsinchu (TW); Ta-Hsun YEH, Hsinchu (TW)

(21) Appl. No.: 17/228,880

(22) Filed: Apr. 13, 2021

(30) Foreign Application Priority Data
Feb. 22, 2021 (TW) 110106192

(51) Int. Cl. H01F 27/29; H01F 17/00; H01F 27/34; H05K 1/16

(52) U.S. Cl. CPC H01F 27/29; H01F 17/0013; H01F 27/34; H05K 1/165; H01F 2017/002; H05K 2201/10015; H05K 2201/10166

(57) ABSTRACT

An inductor and an integrated circuit are provided. The inductor includes a first coil, a second coil, and a third coil. The first coil has a first input terminal and a first output terminal, and the first coil is winded in a first direction from the first input terminal to the first output terminal. The second has a second input terminal and a second output terminal, and the second coil is winded in a second direction which is opposite to the first direction from the second input terminal to the second output terminal. The third has a third input terminal and a third output terminal, and the third input terminal is connected to the first input terminal and the second input terminal.

### CROSS-REFERENCE TO RELATED APPL1CATION

This application claims priority to Taiwan Application Serial Number 110106192, filed Feb. 22, 2021, which is herein incorporated by reference in its entirety.

### BACKGROUND

### Field of Invention

The present disclosure relates to an inductor and an integrated circuit. More particularly, the inductor of the integrated circuit of the present disclosure is formed of coils with different winding directions to eliminate signal interference caused by the transmission lines and the circuits around the integrated circuit, and the bandwidth of the integrated circuit can be increased and the signal distortion can be reduced by adjusting the inductance of the coil.

### Description of Related Art

In the prior art, the number of inductors in a circuit is usually increased to improve the bandwidth and signal distortion. However, the inductor occupies a larger area than other components in the layout of the integrated circuit, so increasing the number of inductors not only increases the overall area of the integrated circuit, but also increases the manufacturing cost. In addition, if the number of inductors is limited in order to control the manufacturing cost, the bandwidth and the signal distortion will not be effectively improved.

Accordingly, an urgent need exists in the art to provide an inductor structure which can improve the bandwidth and the signal distortion while controlling the manufacturing cost.

### SUMMARY

An objective of the present disclosure is to provide an inductor structure which includes three coils, two of the coils are disposed on the same metal layer and winding in opposite directions, and the other coil is disposed on another metal layer and overlapping the two coils. In this way, the inductor structure of the present disclosure can improve the bandwidth and the signal distortion while controlling the manufacturing cost.

To achieve the aforesaid objective, the present disclosure provides an inductor which includes a first coil, a second coil, and a third coil. The first coil includes a first input terminal and a first output terminal, and is formed by winding from the first input terminal to the first output terminal in a first direction. The second coil includes a second input terminal and a second output terminal, and is formed by winding from the second input terminal to the second output terminal in a second direction. The second direction is opposite to the first direction. The third coil includes a third input terminal and a third output terminal, and the third input terminal is connected to the first output terminal and the second input terminal.

In addition, the present disclosure further provides an integrated circuit which includes a first resistor, a second resistor, a first capacitor, a second capacitor, a third capacitor, a fourth capacitor, a first transistor, a second transistor, a first inductor, and a second inductor. The first resistor and the second resistor are electrically connected to a power supply. The first transistor and the second transistor are electrically connected to the current source. The first inductor is electrically connected to the first resistor, the first capacitor, the third capacitor, and the first transistor. The first inductor includes a first coil, a second coil, and a third coil, the first coil is winding in a first direction, and the second coil is winding in a second direction which is opposite to the first direction. The second inductor is electrically connected to the second resistor, the second capacitor, the fourth capacitor, and the second transistor.

The detailed technology and preferred embodiments implemented for the present invention are described in the following paragraphs accompanying the appended drawings for people skilled in this field to well appreciate the features of the claimed invention.

### BRIEF DESCRIPTION OF THE DRAWINGS

The invention can be more fully understood by reading the following detailed description of the embodiment, with reference made to the accompanying drawings as follows:

FIG. 1 is a schematic view of winding direction of the inductor according to the present disclosure;

FIG. 2 is a schematic view of winding direction of the inductor according to the present disclosure;

FIG. 3 is a schematic view of winding direction of the inductor according to the present disclosure;

FIG. 4 is a schematic view of winding direction of the inductor according to the present disclosure;

FIG. 5 is a schematic view of the integrated circuit according to the present disclosure;

FIG. 6 is a schematic view of winding direction of the inductor according to the present disclosure;

FIG. 7 is a schematic view of winding direction of the inductor according to the present disclosure;

FIG. 8 is a schematic view of winding direction of the inductor according to the present disclosure; and

FIG. 9 is a schematic view of winding direction of the inductor according to the present disclosure.

### DETAILED DESCRIPTION

Reference will now be made in detail to the present embodiments of the invention, examples of which are illustrated in the accompanying drawings, and are not intended to limit the present invention to any specific environment, applications or particular implementations described in these embodiments. Therefore, description of these embodiments is only for purpose of illustration rather than to limit the present invention. Wherever possible, the same reference numbers are used in the drawings and the description to refer to the same or like parts. It shall be appreciated that, in the following embodiments and the attached drawings, elements unrelated to the present invention are omitted from depiction; and dimensional relationships among individual elements in the attached drawings are provided only for ease of understanding, but not to limit the actual scale.

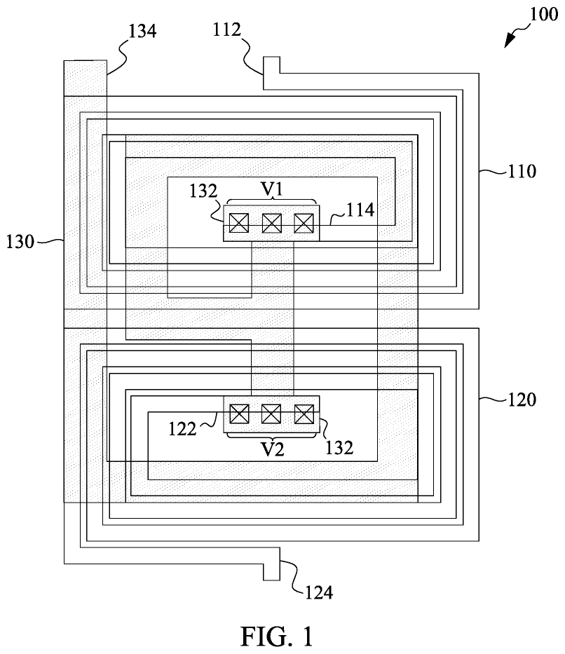

A first embodiment of the present invention is with reference made to FIG. 1 to FIG. 4 which depicts schematic views of winding direction of the inductor respectively according to the present disclosure. The inductor 100 includes a first coil 110, a second coil 120, and a third coil 130. The first coil 110 includes a first input terminal 112 and a first output terminal 114. The first coil 110 is formed by winding from the first input terminal 112 to the first output terminal 114 in a first direction. The first direction may be one of a clockwise direction and a counter clockwise direction. The second coil 120 includes a second input terminal 122 and a second output terminal 124. The second coil 120 is formed by winding from the second input terminal 122 to the second output terminal 124 in a second direction. The second direction may also be one of the clockwise direction and the counter clockwise direction.

In the present invention, the second direction is opposite to the first direction to eliminate signal interference. Moreover, in other embodiments, a first inductance of the first coil 110 and a second inductance of the second coil 120 may set to be the same so that the signal interference caused by the magnetic field of the first coil 110 and the magnetic field of the second coil 120 can be completely eliminated. It shall be appreciated that, the first inductance of the first coil 110 and the second inductance of the second coil 120 may be adjusted based on the operation of the circuit that includes the inductor 100, so the first inductance and the second inductance may also set to be different in response to different circuit design or different layout.

The third coil 130 includes a third input terminal 132 and a third output terminal 134, and the third input terminal 132 is connected to the first output terminal 114 and the second input terminal 122. The third coil 130 is formed by winding from the third input terminal 132 to the third output terminal 134 in one of the first direction and the second direction. In other words, no matter the first direction and the second direction is the clockwise direction or the counter clockwise direction, the winding direction of the third coil 130 can be the same as the first direction of the first coil 110 or the second direction of the second coil 120.

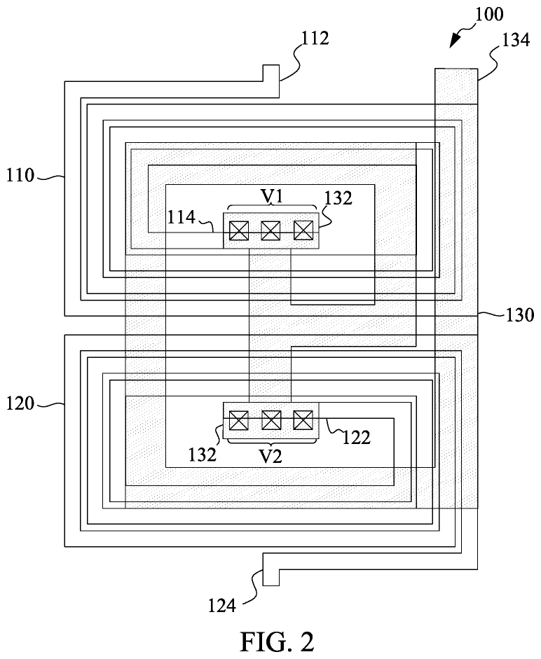

For example, reference is made to FIG. 1 to FIG. 4 which respectively depicts different winding direction combination of the first coil 110, the second coil 120, and the third coil 130 included in the inductor 100. In FIG. 1, the first direction of the first coil 110 is the clockwise direction, the second direction of the second coil 120 is the counter clockwise direction, and the third direction of the third coil 130 is the clockwise direction. In FIG. 2, the first direction of the first coil 110 is the counter clockwise direction, the second direction of the second coil 120 is the clockwise direction, and the third direction of the third coil 130 is the counter clockwise direction.

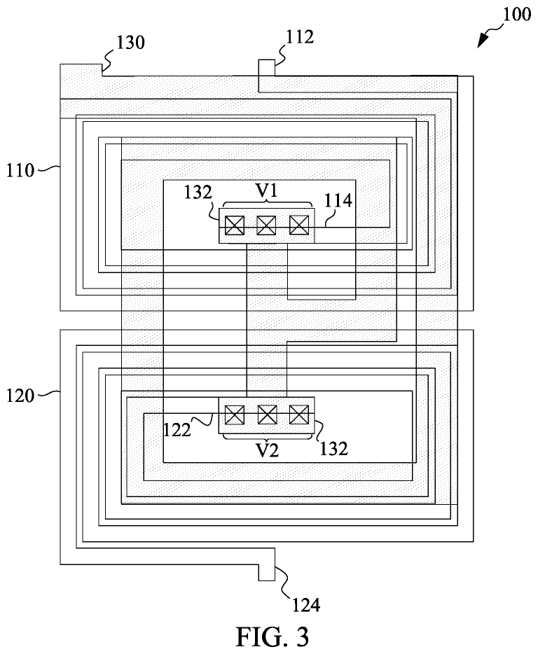

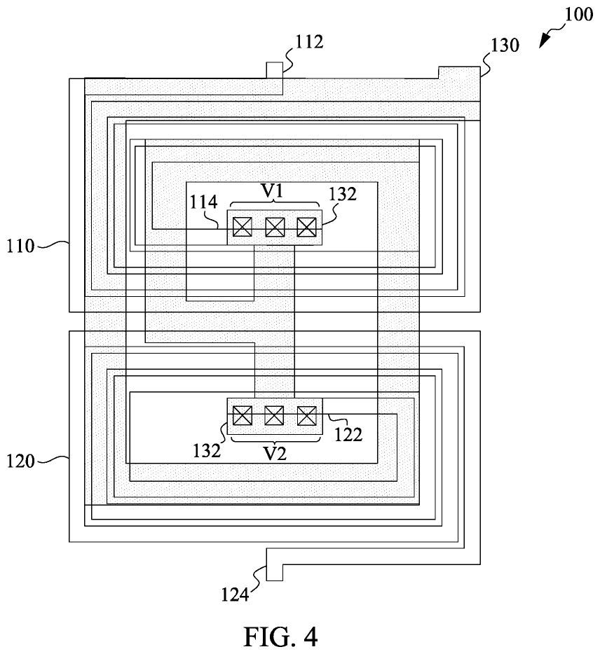

In FIG. 3, the first direction of the first coil 110 is the clockwise direction, the second direction of the second coil 120 is the counter clockwise direction, and the third direction of the third coil 130 is the counter clockwise direction. In FIG. 4, the first direction of the first coil 110 is the counter clockwise direction, the second direction of the second coil 120 is the clockwise direction, and the third direction of the third coil 130 is the clockwise direction.

Furthermore, the first coil 110 and the second coil 120 of the inductor 100 are disposed on a first metal layer, and the third coil 130 is disposed on a second metal layer. In other words, the first coil 110 and the second coil 120 are disposed on the same metal layer in the layout, and the third coil 130 overlaps the first coil 110 and the second coil 120 in a vertical direction. The third input terminal 132 is connected to the first output terminal 114 through a first via V1, and third input terminal 132 is further connected to the second input terminal 122 through a second via V2.

It shall be noted that, the aforementioned first metal layer and second metal layer are only used to distinguish different metal layers, and are not used to limit the number, order, and position of the metal layers in the layout.

In other embodiments, a sum of a first area of the first coil 110 and a second area of the second coil 120 is greater than a third area of the third coil 130, and the total area of the inductor 100 is the sum of the first area of the first coil 110 and the second area of the second coil 120. Compared with the prior art, when three coils need to be arranged in the layout, three separate inductors containing only one coil are usually used which leads the manufacturing cost to remain high. In the present invention, the third coil 130 overlaps the first coil 110 and the second coil 120, so the total area and manufacturing cost of the inductor 100 can be greatly reduced.

In other embodiments, the first inductance of the first coil 110 and the second inductance of the second coil 120 are greater than a third inductance of the third coil 130.

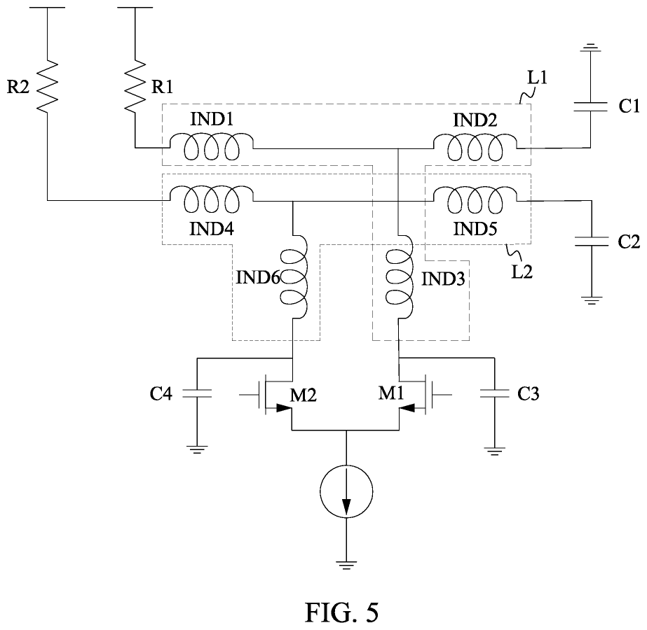

A second embodiment of the present invention is with reference made to FIG. 5 to FIG. 9. FIG. 5 is a schematic view of the integrated circuit including the inductor 100 according to the present disclosure. The integrated circuit 200 includes a first resistor R1, a second resistor R2, a first inductor L1, a second inductor L2, a first capacitor C1, a second capacitor C2, a third capacitor C3, a fourth capacitor C4, a first transistor M1, and a second transistor M2. The first resistor R1 and the second resistor R2 are electrically connected to a power supply. The first transistor M1 and the second transistor M2 are electrically connected to a current source.

The first inductor L1 is electrically connected to the first resistor R1, the first capacitor C1, the third capacitor C3, and the first transistor M1. In detail, the first inductor L1 includes a first coil IND1, a second coil IND2, and a third coil IND3. In the integrated circuit 200, the first coil IND1, the second coil IND2, and the third coil IND3 form the first inductor L1 which is a T-shaped coil with three terminals. A first terminal of the first inductor L1 is connected to the first resistor R1, a second terminal of the first inductor L1 is connected to the first capacitor C1, and a third terminal of the first inductor L1 is connected to the first transistor M1.

Similarly, the second inductor L2 is electrically connected to the second resistor R2, the second capacitor C2, the fourth capacitor C4, and the second transistor M2. The second inductor L2 includes a fourth coil IND4, a fifth coil IND5, and a sixth coil IND6. In the integrated circuit 200, the fourth coil IND4, the fifth coil IND5, and the sixth coil IND6 form the second inductor L2 which is also a T-shaped coil with three terminals. A first terminal of the second inductor L2 is connected to the second resistor R2, a second terminal of the second inductor L2 is connected to the second capacitor C2, and a third terminal of the second inductor L2 is connected to the fourth capacitor C4 and the second transistor M2.

In the layout of the integrated circuit 200, the first coil IND1 of the first inductor L1 is winding in a first direction, and the second coil IND2 of the first inductor L1 is winding in a second direction. In the present invention, the second direction is opposite to the first direction to reduce signal interference. Moreover, in other embodiments, a first inductance of the first coil IND1 and a second inductance of the second coil IND2 may set to be the same so that the signal interference caused by the magnetic field of the first coil IND1 and the magnetic field of the second coil IND2 can be completely eliminated.

Since the fourth coil IND4 is adjacent to the first coil IND1, in order to reduce the external interference of the integrated circuit 200, the fourth coil IND4 is winding in the second direction, and the fifth coil IND5 is winding in the first direction. In other words, the winding direction of the fourth coil IND4 needs to be opposite to the winding direction of the first coil IND1, and the winding direction of the fifth coil IND5 needs to be opposite to the winding direction of the second coil IND2 and the winding direction of the fourth coil IND4. Similarly, a fourth inductance of the fourth coil IND4 and a fifth inductance of the fifth coil IND5 may set to be the same as the first inductance and the second inductance so that the signal interference caused by the magnetic field of the fourth coil IND4 and the magnetic field of the fifth coil IND5 can be completely eliminated.

The third coil IND3 and the sixth coil IND6 may be winding in the first direction or the second direction. When the third coil IND3 is winding in the first direction, the sixth coil IND6 is winding in the second direction, and when the third coil IND3 is winding in the second direction, the sixth coil IND6 is winding in the first direction. A third inductance of the third coil IND3 and a sixth inductance of the sixth coil IND6 may set to be the same to eliminate the signal interference caused by the magnetic field of the third coil IND3 and magnetic field of the sixth coil IND6.

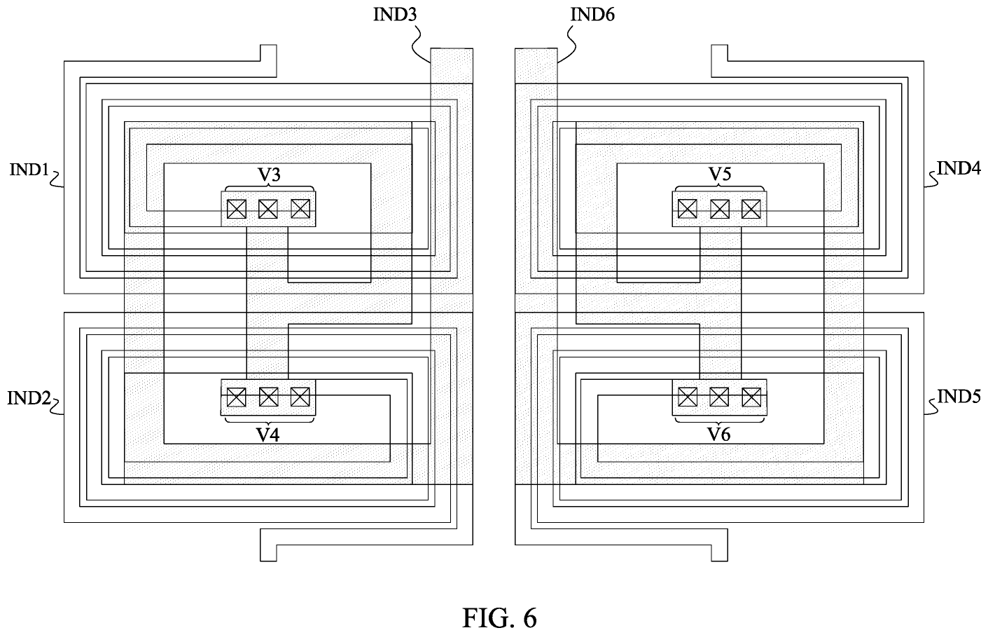

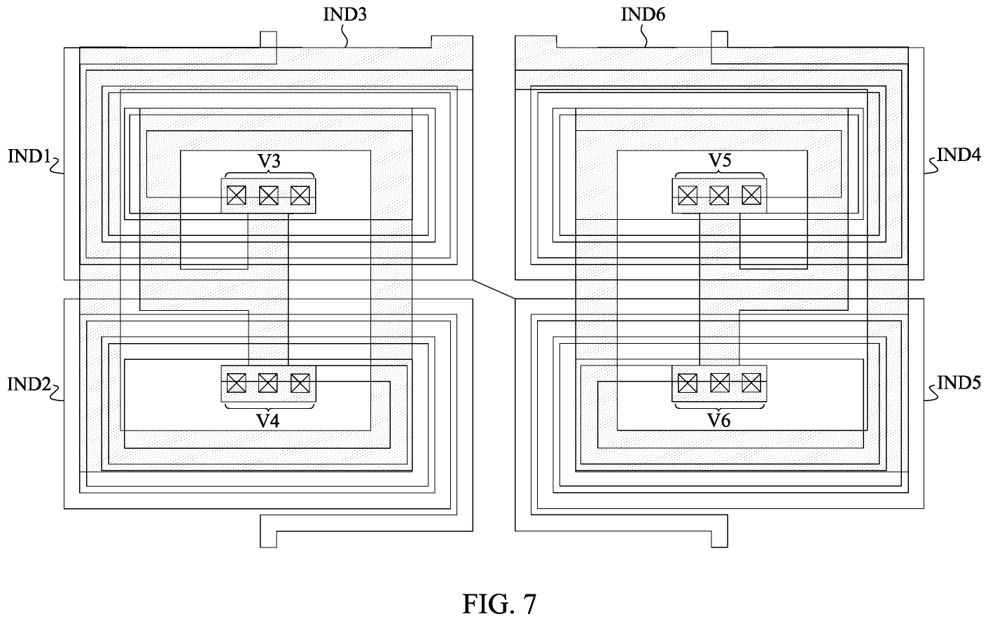

For example, reference is made to FIG. 6 to FIG. 9 which respectively depicts different winding direction combination of the first coil IND1, the second coil IND2, and the third coil IND3 included in the first inductor L1, and different winding direction combination of the fourth coil IND4, the fifth coil IND5, and the sixth coil IND6 included in the second inductor L2. In FIG. 6, the first direction of the first coil IND1 is the counter clockwise direction, the second direction of the second coil IND2 is the clockwise direction, the third coil IND3 is winding in the counter clockwise direction, the fourth coil IND4 is winding in the clockwise direction, the fifth coil IND5 is winding in the counter clockwise direction, and the sixth coil IND6 is winding in the clockwise direction. In FIG. 7, the first direction of the first coil IND1 is the counter clockwise direction, the second direction of the second coil IND2 is the clockwise direction, the third coil IND3 is winding in the clockwise direction, the fourth coil IND4 is winding in the clockwise direction, the fifth coil IND5 is winding in the counter clockwise direction, and the sixth coil IND6 is winding in the counter clockwise direction.

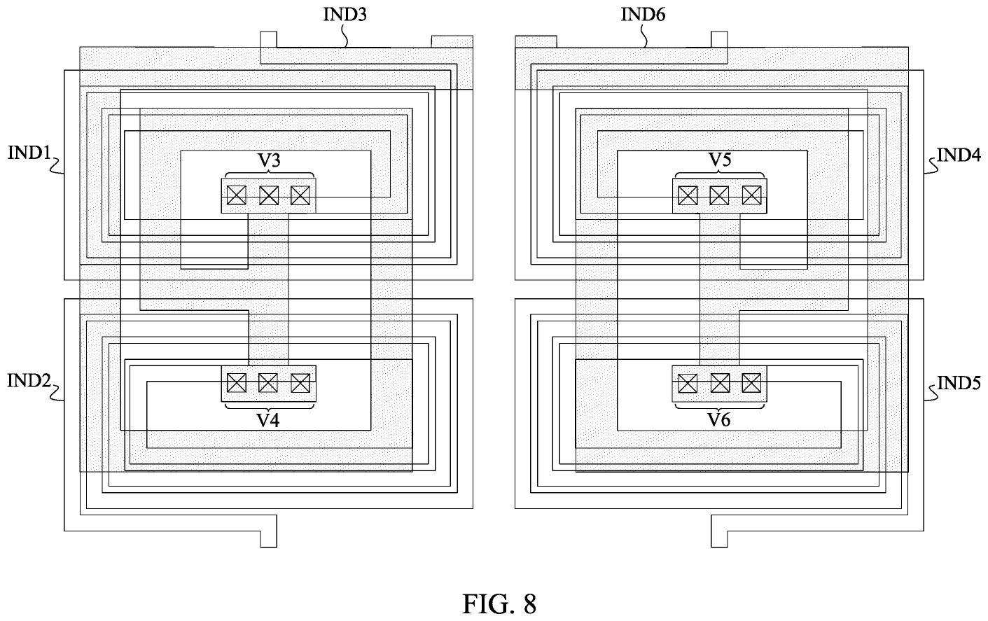

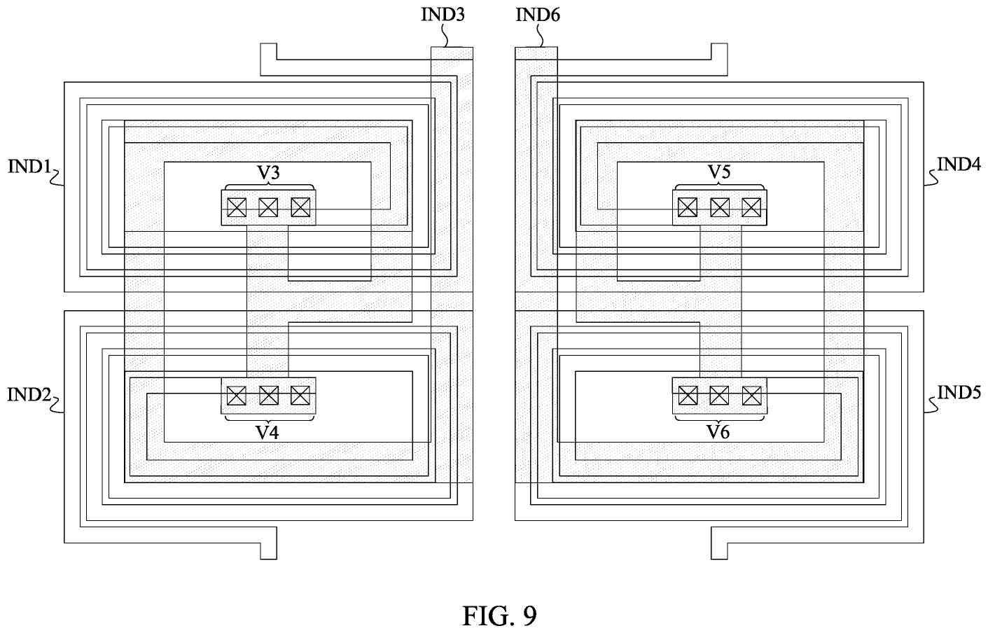

In FIG. 8, the first direction of the first coil IND1 is the clockwise direction, the second direction of the second coil IND2 is the counter clockwise direction, the third coil IND3 is winding in the clockwise direction, the fourth coil IND4 is winding in the counter clockwise direction, the fifth coil IND5 is winding in the clockwise direction, and the sixth coil IND6 is winding in the counter clockwise direction. In FIG. 9, the first direction of the first coil IND1 is the clockwise direction, the second direction of the second coil IND2 is the counter clockwise direction, the third coil IND3 is winding in the counter clockwise direction, the fourth coil IND4 is winding in the counter clockwise direction, the fifth coil IND5 is winding in the clockwise direction, and the sixth coil IND6 is winding in the clockwise direction.

The first coil IND1, the second coil IND2, the fourth coil IND4, and the fifth coil IND5 are disposed on the first metal layer, and the third coil IND3 and the sixth coil IND6 are disposed on a second metal layer in the layout of the integrated circuit 200. The third coil IND3 overlaps the first coil IND1 and the second coil IND2 in the vertical direction, and the third coil IND3 is connected to the first coil IND1 through a first via V3 and connected to the second coil IND2 through a second via V4 to reduce total area and manufacturing cost of the inductor L1. Similarly, the sixth coil IND6 overlaps the fourth coil IND4 and the fifth coil IND5 in the vertical direction, and the sixth coil IND6 is connected to the fourth coil IND4 through a third via V5 and connected to the fifth coil IND5 through a fourth via V6.

It shall be noted that, the aforementioned first metal layer and second metal layer are only used to distinguish different metal layers, and are not used to limit the number, order, and position of the metal layers in the layout.

In other embodiment, a sum of a first area of the first coil IND1 and a second area of the second coil IND2 is greater than a third area of the third coil IND3, and a sum of the fourth area of the fourth coil IND4 and a fifth area of the fifth coil IND5 is greater than a sixth area of the sixth coil IND6. Compared with the prior art, when six coils need to be arranged in the layout, six separate inductors containing only one coil are usually used which leads the manufacturing cost to remain high. In the present invention, the third coil IND3 overlaps the first coil IND1 and the second coil IND2, and the sixth coil IND6 overlaps the fourth coil IND4 and the fifth coil IND5, the total area and manufacturing cost of the inductor L1 and the inductor L2 can be greatly reduced.

In other embodiment, one of the first inductance, the second inductance, the fourth inductance and the fifth inductance is greater than one of the third inductance and the sixth inductance. In other embodiment, compared with an integrated circuit that does not use an inductor or an integrated circuit that uses an inductor with a single coil structure, the inductor structure of the present invention can increase the bandwidth of the integrated circuit 200.

According to the above descriptions, the inductor structure of the present invention is designed as multiple coils with stacked structure and adjacent coils are winded in opposite directions, the area of the inductor and external interference can be reduced. In addition, by setting the inductor of the present invention in the integrated circuit, the pole zero cancellation can be achieved and the bandwidth of the integrated circuit can further be increased (i.e., 3 db bandwidth extension).

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An inductor, comprising:
a first coil comprising a first input terminal and a first output terminal, and being formed by winding from the first input terminal to the first output terminal in a first direction;
a second coil comprising a second input terminal and a second output terminal, and being formed by winding from the second input terminal to the second output terminal in a second direction, wherein the second direction is opposite to the first direction; and
a third coil comprising a third input terminal and a third output terminal, wherein the third input terminal is connected to the first output terminal and the second input terminal.

2. The inductor of claim 1, wherein the third coil is formed by winding from the third input terminal to the third output terminal in one of the first direction and the second direction.

3. The inductor of claim 1, wherein when the first direction is a clockwise direction, the second direction is a counter clockwise direction, and the third coil is formed by winding from the third input terminal to the third output terminal in the counter clockwise direction.

4. The inductor of claim 1, wherein when the first direction is a counter clockwise direction, the second direction is a clockwise direction, and the third coil is formed by winding from the third input terminal to the third output terminal in the counter clockwise direction.

5. The inductor of claim 1, wherein when the first direction is a counter clockwise direction, the second direction is a clockwise direction, and the third coil is formed by winding from the third input terminal to the third output terminal in the clockwise direction.

6. The inductor of claim 1, wherein the first coil and the second coil are disposed on a first metal layer, and the third coil is disposed on a second metal layer, the third input terminal is connected to the first output terminal through a first via, and third input terminal is connected to the second input terminal through a second via.

7. The inductor of claim 1, wherein the third coil overlaps the first coil and the second coil in a vertical direction.

8. The inductor of claim 1, wherein a sum of a first area of the first coil and a second area of the second coil is greater than a third area of the third coil.

9. The inductor of claim 1, wherein a first inductance of the first coil is the same as a second inductance of the second coil.

10. The inductor of claim 9, wherein the first inductance of the first coil and the second inductance of the second coil are greater than a third inductance of the third coil.

11. An integrated circuit, comprising:
a first resistor electrically connected to a power supply;
a second resistor electrically connected to the power supply;
a first capacitor;
a second capacitor;
a third capacitor;
a fourth capacitor;
a first transistor electrically connected to a current source;
a second transistor electrically connected to the current source;
a first inductor electrically connected to the first resistor, the first capacitor, the third capacitor, and the first transistor, wherein the first inductor comprises a first coil, a second coil, and a third coil, the first coil is winding in a first direction, and the second coil is winding in a second direction which is opposite to the first direction; and
a second inductor electrically connected to the second resistor, the second capacitor, the fourth capacitor, and the second transistor.

12. The integrated circuit of claim 11, wherein the second inductor comprises a fourth coil, a fifth coil, and a sixth coil, the fourth coil is winding in the second direction, and the fifth coil is winding in the first direction.

13. The integrated circuit of claim 12, wherein when the third coil is winding in the first direction, the sixth coil is winding in the second direction, and when the third coil is winding in the second direction, the sixth coil is winding in the first direction.

14. The integrated circuit of claim 12, wherein when the first direction is a counter clockwise direction, the second direction is a clockwise direction, the third coil is winding in the counter clockwise direction, and the sixth coil is winding in the clockwise direction.

15. The integrated circuit of claim 12, wherein when the first direction is a counter clockwise direction, the second direction is a clockwise direction, the third coil is winding in the clockwise direction, and the sixth coil is winding in the counter clockwise direction.

16. The integrated circuit of claim 12, wherein the first coil, the second coil, the fourth coil, and the fifth coil are disposed on the first metal layer, the third coil and the sixth coil are disposed on a second metal layer, the third coil is connected to the first coil through a first via and connected to the second coil through a second via, and the sixth coil is connected to the fourth coil through a third via and connected to the fifth coil through a fourth via.

17. The integrated circuit of claim 12, wherein the third coil overlaps the first coil and the second coil in a vertical direction, and the sixth coil overlaps the fourth coil and the fifth coil in the vertical direction.

18. The integrated circuit of claim 12, wherein a sum of a first area of the first coil and a second area of the second coil is greater than a third area of the third coil, and a sum of the fourth area of the fourth coil and a fifth area of the fifth coil is greater than a sixth area of the sixth coil.

19. The integrated circuit of claim 12, wherein a first inductance of the first coil, a second inductance of the second coil, a fourth inductance of the fourth coil, and a fifth inductance of the fifth coil are the same, and a third inductance of the third coil and a sixth inductance of the sixth coil are the same.

20. The integrated circuit of claim 19, wherein one of the first inductance, the second inductance, the fourth inductance and the fifth inductance is greater than one of the third inductance and the sixth inductance.
